(19) United States
(12) Patent Application Publication
(10) Pub. No.: US 2012/0291275 A1
(43) Pub. Date: Nov. 22, 2012

(54) METHOD OF FORMING METAL INTERCONNECTION LINE ON FLEXIBLE SUBSTRATE

(75) Inventors: Jong-Joo RHA, Gyeongsangnam-do (KR); Kee-Seok NAM, Gyeongsangnam-do (KR); Jung-Dae KWON, Gyeongsangnam-do (KR); Kyu-Hwan LEE, Gyeongsangnam-do (KR); Jong-Soo BAE, Gyeongsangnam-do (KR); Joo-Yul LEE, Gyeongsangnam-do (KR); Jong-Soo KO, Busan (KR)

(73) Assignee: KOREA INSTITUTE OF MACHINERY & MATERIALS, Daejeon (KR)

(21) Appl. No.: 13/337,650

(22) Filed: Dec. 27, 2011

(30) Foreign Application Priority Data
May 19, 2011 (KR) 10-2011-0047107
Dec. 20, 2011 (KR) 10-2011-0138131

(51) Int. Cl. H05K 3/10

(52) U.S. Cl. 29/846

(57) ABSTRACT

Provided is a method of forming a metal interconnection line on a flexible substrate, wherein the method includes: coating a hard mask layer on at least one surface of the flexible substrate, followed by performing photolithography thereon to form a predetermined hard mask pattern; etching a portion of the flexible substrate by using the hard mask pattern as a mask to form a trench; plasma treating the inside of the trench by using a treatment gas for pre-treating the flexible substrate; coating a seed layer inside the trench; removing the hard mask pattern; and filling the inside of the trench coated with the seed layer with metal. A metal interconnection line formed by using the method may have a strong adhesion force with respect to the flexible substrate.

### CROSS-REFERENCE TO RELATED PATENT APPLICATION

This application claims the benefit of Korean Patent Application No. 10-2011-0047107, filed on May 19, 2011, in the Korean Intellectual Property Office, the disclosure of which is incorporated herein in its entirety by reference.

### BACKGROUND OF THE INVENTION

1. Field of the Invention

The present invention relates to a method of forming a metal interconnection line on a flexible substrate, and in particular, to a method of forming a metal interconnection line that enables electrical connection between a plurality of part devices disposed on a surface of a flexible substrate for various electronic devices or display devices.

2. Description of the Related Art

A flexible substrate refers to a substrate that provides a surface on which part devices, such as various chips or passive devices, are mounted. The flexible substrate may flexibly respond when a substrate needs to be moved, or needs to be bent to insert part devices. The flexible substrate is also called a ductile substrate due to its well-bendable ductility. The flexible substrate is manufactured by using a polymer material, and according to the number of interconnection line circuit surfaces, the flexible substrate can be classified as a single-surface substrate, a both-surface substrate, a multi-layered substrate, or the like. On a surface of the flexible substrate, as a part device, a plurality of active devices, such as a semiconductor chip, or a plurality of passive devices, such as a resistor or a condenser, are mounted, and metal interconnection lines for transmitting or receiving electrical signals are formed either between these part devices or between the part devices and an external input or output device. A technology for forming such metal interconnection lines provides a foundation for the electronic part industry, and is a core material technology that is applicable to almost all electronic parts. In particular, due to an increasing demand for high-integration and high-performance electronic parts, a fine pitch of a interconnection line technology is more importantly regarded, and embodiment of a metal interconnection line having a high aspect ratio obtained by accomplishing a fine pitch is desperately required. Also, the rapid increase in demand for flexible devices using flexible substrates adds such requirements as large-size manufacturing, flexibility, environmentally friendliness, and low manufacturing costs, which are required in various other applications, such as displays, illumination devices, organic solar cells, or the like, to a metal interconnection line technology applied onto a flexible substrate.

However, in these fields, conventional interconnection line technologies based on an etching process may fail to comply with the requirements. That is, to prevent a decrease in resistance which occurs in accomplishing a fine pitch, a thickness of an interconnection line needs to be increased, and in such a condition, it would be difficult to stably form a metal interconnection line having 20 μm or less of an interconnection line width.

### SUMMARY OF THE INVENTION

The present invention provides a method of economically forming a metal interconnection line having strong adhesion force with respect to a flexible substrate.

According to an aspect of the present invention, there is provided a method of forming a metal interconnection line on a flexible substrate, wherein the method includes: coating a hard mask layer on at least one surface of the flexible substrate, followed by performing photolithography thereon to form a hard mask pattern; etching a portion of the flexible substrate by using the hard mask pattern as a mask to form a trench; plasma treating the inside of the trench by using a treatment gas for pre-treating the flexible substrate; coating a seed layer inside the trench; removing the hard mask pattern; and filling the inside of the trench coated with the seed layer, with metal.

The removing of the hard mask pattern may be performed before or after the coating the inside of the trench with the seed layer.

The method may further include: forming a passivation film on the hard mask pattern by ink-coating using a roller, after the portion of the flexible substrate is etched by using the hard mask pattern as a mask to form the trench; and removing the passivation film after the seed layer is formed inside the trench.

The hard mask layer may include chrominum (Cr) or aluminum (Al).

The hard mask layer may have a double layer structure formed by sequentially depositing Cr and Al in this stated order.

A width of the trench may be greater than 0 and equal to or greater than 20 μm.

The plasma-treating of the inside of the trench may be performed using atmospheric pressure plasma.

The treatment gas may be an ammonia gas or a mixed gas including an ammonia gas, a nitrogen gas, a helium gas, and a hydrogen gas.

The seed layer may include a palladium layer. As another example, the seed layer may include a palladium/nickel composite layer prepared by coating a palladium layer and coating a nickel layer on the palladium layer.

The method may further include washing the palladium layer with a sulfuric acid after the palladium layer is formed.

The palladium layer or the palladium/nickel composite layer may be formed by plating.

The filling the inside of the trench with metal may be filing the inside of the trench with copper by plating.

### BRIEF DESCRIPTION OF THE DRAWINGS

The above and other features and advantages of the present invention will become more apparent by describing in detail exemplary embodiments thereof with reference to the attached drawings in which:

FIGS. 1 to 16 are cross-sectional views illustrating a method of forming a metal interconnection line according to an embodiment of the present invention;

FIG. 17 is an electron microscopic plan image of a sample (W:L=10 μm:10 μm) including a photo-sensitive film patterned on a chrominum hard mask according to an embodiment of the present invention;

FIGS. 18A and 18B are electron microscopic images of a cross-section of polyimide substrate after etching;

FIGS. 19A and 19B are electron microscopic images of a surface of polyimide substrate after etching; and

FIG. 20 shows a surface image of a polyimide substrate having trenches filled with copper.

### DETAILED DESCRIPTION OF THE INVENTION

Reference will now be made in detail to embodiments, examples of which are illustrated in the accompanying drawings. In this regard, the present embodiments may have different forms and should not be construed as being limited to the descriptions set forth herein. Accordingly, the embodiments are merely described below, by referring to the figures, to explain aspects of the present description. Also, in the drawings, sizes of the respective elements may be exaggerated for ease of convenience.

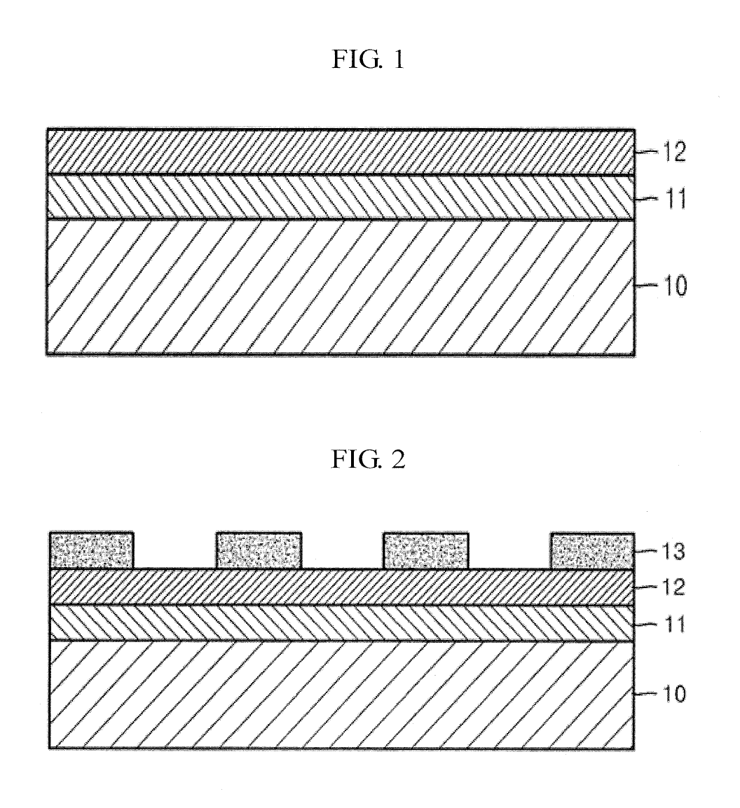

FIGS. 1 to 10 are cross-sectional views illustrating a method of forming a metal interconnection line on a flexible substrate according to a first embodiment of the present invention.

Referring to FIG. 1, a flexible substrate 10 is provided. The flexible substrate 10 may include a polymer material or an insulating material having flexibility. On least one surface of the flexible substrate 10, a hard mask layer 11 is deposited.

The hard mask layer 11 is to be formed in a predetermined pattern and then used as a mask when the flexible substrate 10 is etched. The hard mask layer 11 may include, for example, chrominum (Cr) or aluminum (Al). When Al is used, compared to Cr, an excellent selectivity ratio characteristic with respect to nickel, which is used to form a seed layer, may be obtained and thus, damage on nickel occurring when a hard mask is removed may be reduced. In this case, however, the adhesion property of Al with respect to a flexible substrate formed of a polymer may be reduced compared to Cr. Accordingly, to use the advantage of Al and to improve the adhesion force with respect to the flexible substrate at the same time, a hard mask having a Cr/Al double-layer structure formed by sequentially depositing Cr and Al in this stated order may be used. The hard mask layer 11 may be formed by depositing, such as sputtering or vacuum evaporation.

The hard mask layer 11 may be formed in a predetermined pattern by using a photolithography process, which is widely known in a micro-pattern formation field, such as a semiconductor fabrication process. The photolithography process used herein includes a photography process in which a photoresist film applied on a substrate is exposed to light and developed to form a predetermined pattern and an etching process in which a portion of the substrate is removed by chemically etching while the formed pattern is used as a mask.

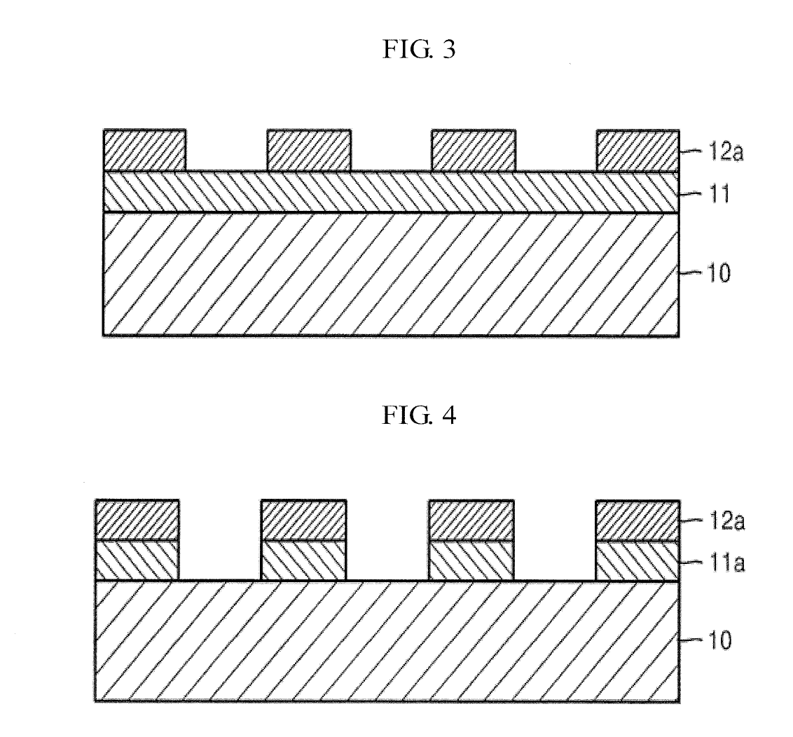

To pattern the hard mask layer 11 by photolithography, a photoresist film 12 is coated on the whole surface of the hard mask layer 11 and then, as illustrated in FIG. 2, the photoresist film 12 is exposed and developed by using a mask 13 to form a photoresist film pattern 12a as illustrated in FIG. 3.

Then, as illustrated in FIG. 4, etching is performed thereon by using the photoresist film pattern 12a as a mask to pattern the hard mask layer 11 to form a hard mask pattern 11a having a predetermined pattern.

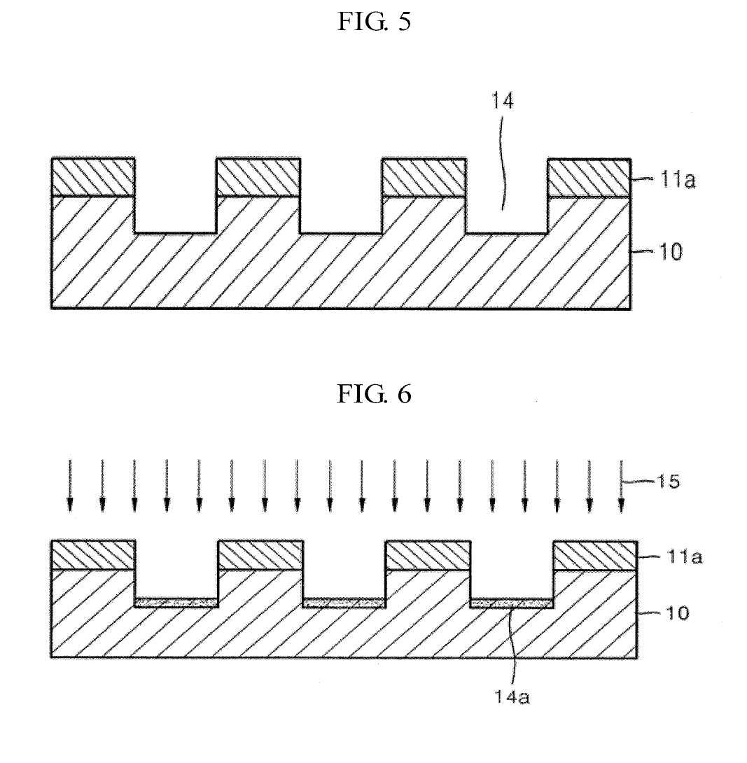

Then, as illustrated in FIG. 5, a portion of a surface of the flexible substrate 10 which is not shielded and is exposed by the hard mask pattern 11a through the etching is etched to form a trench 14 having a predetermined depth. The trench 14 is a region on which a metal interconnection line for electrical connection between various part devices mounted on the flexible substrate 10 is formed, and will be filled with metal in a subsequent process.

In this regard, if the flexible substrate 10 and the photoresist film pattern 12a are all formed of a polymer material, when the flexible substrate 10 is etched, the photoresist film pattern 12a formed of a material similar to that of the flexible substrate 10 also reacts with an etchant and thus, the photoresist film pattern 12a may fail to act as a mask and may be removed as illustrated in FIG. 5 during the etching.

That is, typically, etching is performed by reacting an etch subject with an etchant to evaporate or dissolve the etch subject to remove a portion in which the etch subject has reacted with the etchant. Accordingly, when the flexible substrate 10 and the photoresist film pattern 12a are formed of polymer materials similar to each other, an etchant for etching the flexible substrate 10 may also react with the photoresist film pattern 12a and thus the photoresist film pattern 12a may be removed by the etching.

However, according to the present embodiment, the hard mask pattern 11a formed of a metallic material, such as Cr, is formed under the photoresist film pattern 12a. Thus, even when the photoresist film pattern 12a is completely removed when the flexible substrate 10 is etched, the hard mask pattern 11a still performs as a mask. Accordingly, only a portion of the flexible substrate 10 on which the trench 14 is to be formed, that is, a portion of the flexible substrate 10 on which the hard mask pattern 12a is not formed is stably etched.

The etching may be a dry etching process using plasma or a wet etching process using an etching solution. When dry etching is used, etching may be performed using plasma under atmospheric conditions. In this case, a depth of the trench 14 may be controlled by adjusting etching conditions, for example, an etching time or an etching rate.

The greater depth the trench 14 has, a cross section of a metal interconnection line has the greater area and a contact surface between the metal interconnection line and the flexible substrate 10 has the greater area. Accordingly, even when the width of the metal interconnection line is reduced, by increasing the depth of the trench 14 to control the aspect ratio of the trench 14, an adhesion between the metal interconnection line and the flexible substrate 10 may be increased while the resistance of the metal interconnection line is reduced.

For example, the trench 14 may have a width of 20 μm or less, and in this case, the depth of the trench 14 may be appropriately determined in consideration of the resistance of the metal interconnection line and the contact area between the metal interconnection line and the flexible substrate 10.

After the trench 14 is formed on the flexible substrate 10, plasma is generated from a treatment gas for pre-treating the flexible substrate 10 and then an inside of the trench 14 is treated with the plasma. In this case, the treatment gas refers to a gas that is introduced into a chamber to plasma-treat the surface of the flexible substrate 10. Due to the plasma treatment using the treatment gas, an adhesion force between a seed layer, which will be formed in a subsequent process, and the flexible substrate 10 will be increased.

Accordingly, after plasma is generated by ionizing the treatment gas, as illustrated in FIG. 6, the surface of the flexible substrate 10 on which the hard mask pattern 11a and the trench 14 are formed is exposed to a particular radical included in the plasma in a direction indicated by an arrow 15, and thus even the inside of the trench 14 are allowed to be treated with the plasma.

The plasma treatment may be performed in a chamber in which the flexible substrate 10 is placed. The plasma may be formed by ionizing the treatment gas after the treatment gas is introduced into the chamber, and a cation of the formed plasma may move in a high speed toward the flexible substrate 10 due to a negative voltage applied to the flexible substrate 10, thereby physicochemically reforming the surface of the flexible substrate 10.

Accordingly, the chamber may include an electrode for supplying energy for ionizing the treatment gas and a device for applying a voltage to a flexible substrate placed inside the chamber. In this case, the chamber may be a vacuum chamber in which a vacuum atmosphere is maintained to generate plasma, or a chamber for forming atmospheric pressure plasma.

The treatment gas may include, for example, an amine-based gas, when the flexible substrate 10 includes a polyimide. The amine-based gas may be an ammonia(NH₃) gas, the treatment gas may be an ammonia gas or a mixed gas including an ammonia gas, a nitrogen gas, a helium gas, and a hydrogen gas.

When plasma of the amine-based gas is used to treat the surface of the polyimide substrate, on a region that has been treated with plasma, metal, such as palladium (Pd), for use as a seed layer may grow into a seed layer having strong adhesion force and a predetermined thickness.

In this case, because the hard mask pattern 11a formed on the flexible substrate 10 may function as a mask even during the plasma treatment, the plasma treatment may be able to be performed only on the portion of the flexible substrate 10 on which the hard mask pattern 11a is not formed. Accordingly, when the plasma treatment is completely performed, as illustrated in 6, a plasma treatment region 14a may be formed only inside the trench 14a exposed by the hard mask pattern 11a.

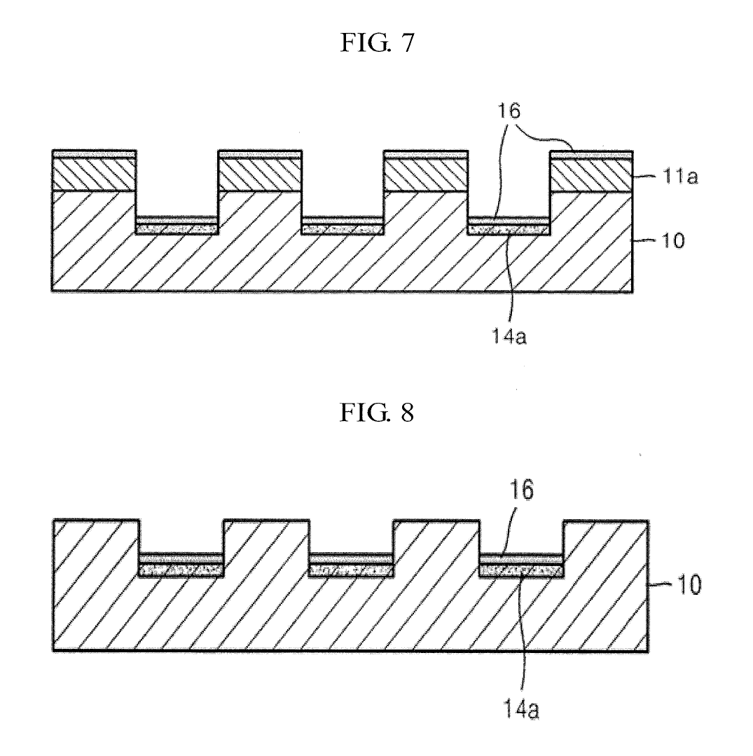

When the plasma treatment is completely performed, as illustrated in FIG. 7, a seed layer 16 is formed inside the trench 14 having the plasma treatment region 14a. The seed layer 16 is a layer that provides a seed for growing metal filling the trench 14, may be, for example, a palladium layer. Another example of the seed layer 16 is a palladium/nickel composite layer formed by sequentially forming a palladium layer and a nickel layer in this stated order, that is, a double layer formed by sequentially depositing palladium and nickel in this stated order.

Regarding the palladium/nickel composite layer, a palladium layer is formed and then washed with a sulfuric acid, followed by the formation of the nickel layer thereon.

The palladium layer or the nickel layer that constitutes the seed layer may be performed by plating. In this case, the plating may include a typical electroplating and a electroless plating.

In this case, the seed layer 16 may also be formed on the hard mask pattern 11a. However, because the hard mask pattern 11a is removed in a subsequent process, the seed layer 16 may remain on only the plasma treatment region 14a inside the trench 14 as illustrated in FIG. 8.

The hard mask pattern 11a may be selectively removed by either wet etching using an etching solution for dissolving only a material, for example, Cr or Al, that constitutes the hard mask pattern 11a, or dry etching using an etching gas.

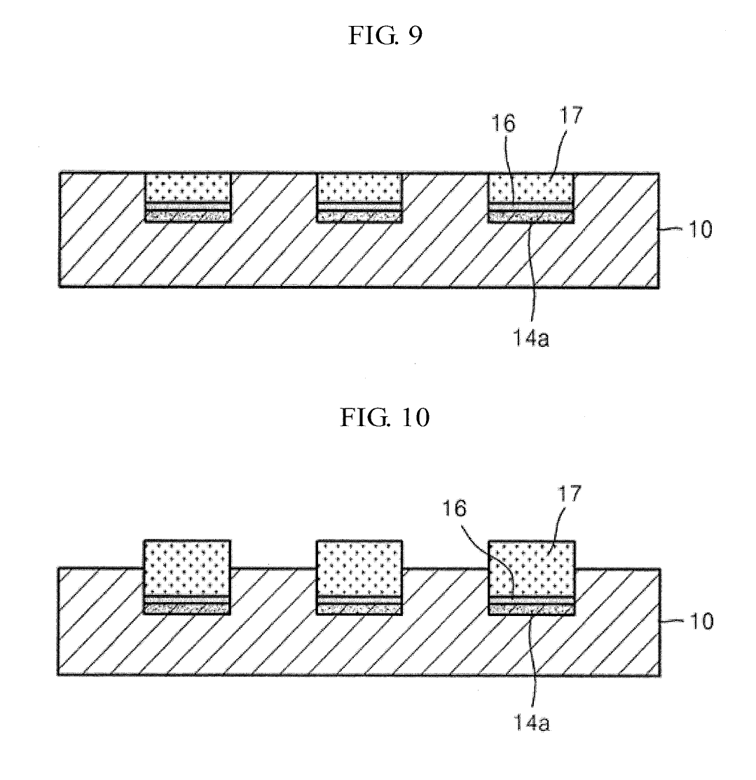

After the hard mask pattern 11a is removed, as illustrated in FIG. 9, the trench 14 is filled by selectively growing metal inside the trench 14 in which the seed layer 16 is formed, thereby forming a metal interconnection line 17. To do this, the inside of the trench 14 may be filled by, for example, plating copper. By the plating, copper may selectively grow on the seed layer 16, for example, a region on which a palladium layer or a palladium/nickel composite layer is formed. In this case, the plating may include electroplating and electroless plating.

As described above, because the width of the trench 14 may be 20 μm or lower, the line width of the metal interconnection line 17 formed by filling the trench 14 may also be 20 μm or less.

Also, in FIG. 9, the metal interconnection line 17 fills only the inside of the trench 14 so that an upper surface of the metal interconnection line is positioned at the same or lower level than the surface of the flexible substrate 10. However, this structure is an example only, and for example, as illustrated in 10, the metal interconnection line 17 may protrude from the surface of the flexible substrate 10.

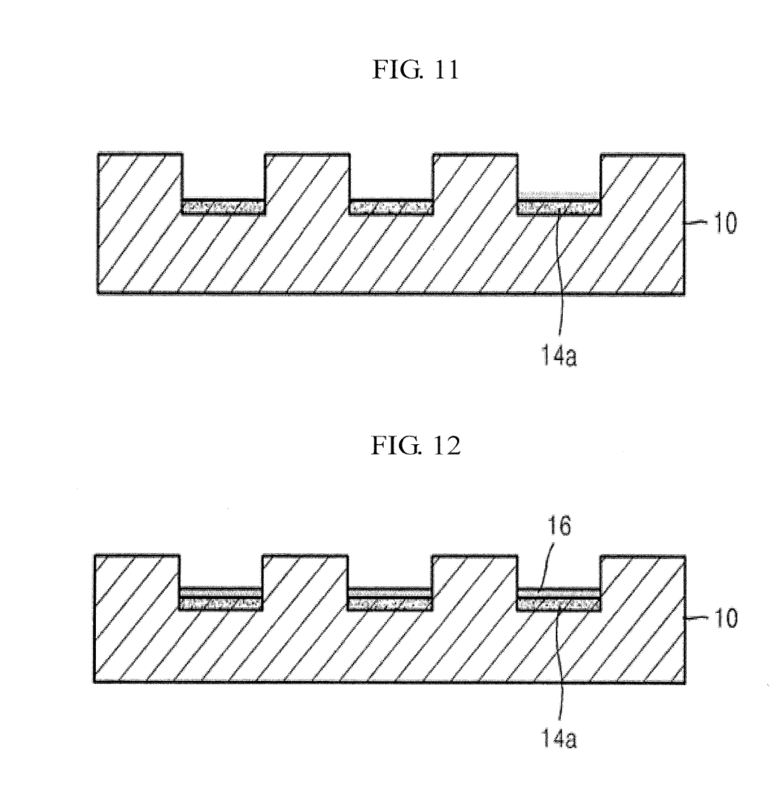

FIGS. 11 and 12 are views illustrating a method of forming a metal interconnection line on a flexible substrate according to a second embodiment of the present invention, and in particular, views to explain a difference between the methods according to the first and second embodiments.

In the present embodiment, the method according to the first embodiment is performed up to the process in which as illustrated in FIG. 6, the surface of the flexible substrate 10 on which the hard mask pattern 11a is formed is treated with plasma. The difference between the methods according to the first and second embodiments is that after the plasma treatment is completely performed, as illustrated in FIG. 11, the hard mask pattern 11a is removed and then a seed layer 16 is formed in a subsequent process.

Because the plasma treatment region 14a is formed inside the trench 14, the seed layer 16 may be selectively formed only inside the trench 14. Then, the trench 14 is filled according to the same method as the method according to the first embodiment.

FIGS. 13 to 16 are views illustrating a method of forming a metal interconnection line on a flexible substrate according to a third embodiment of the present invention, and in particular, views to explain a difference between the methods according to the first and third embodiments. In the present embodiment, the method according to the first embodiment is performed up to the process in which as illustrated in FIG. 5, the hard mask pattern 11a is formed on the surface of the flexible substrate 10 and the resultant structure is etched to form the trench 14.

The difference between the methods according to the first and third embodiments is that before the plasma treatment, a passivation film 18 is formed on the hard mask pattern 11a according to the third embodiment.

In this case, the passivation film 18 is formed on only the hard mask pattern 11a by coating an ink having a predetermined viscosity thereon by using a roller. That is, as illustrated in FIG. 5, the hard mask pattern 11a and the trench 14 disposed around the hard mask pattern 11a have different height levels. Accordingly, when a roller is rolled on the hard mask pattern 11a of the flexible substrate 10 while the roller directly contacts the hard mask pattern 11a, an ink that has been present on the surface of the roller may be transferred onto only the hard mask pattern 11a in the direct contact with the roller. Then, drying is performed thereon to completely form the passivation film 18.

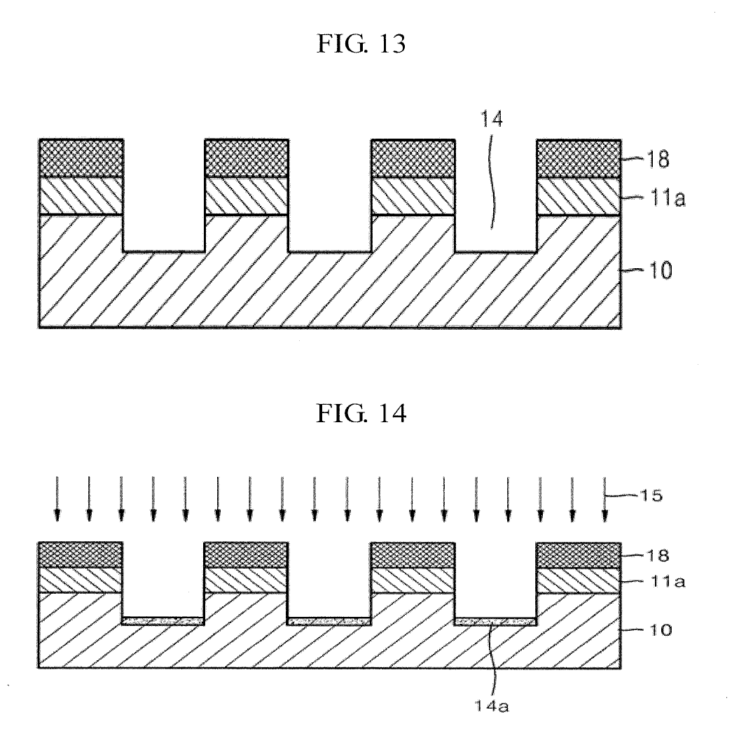

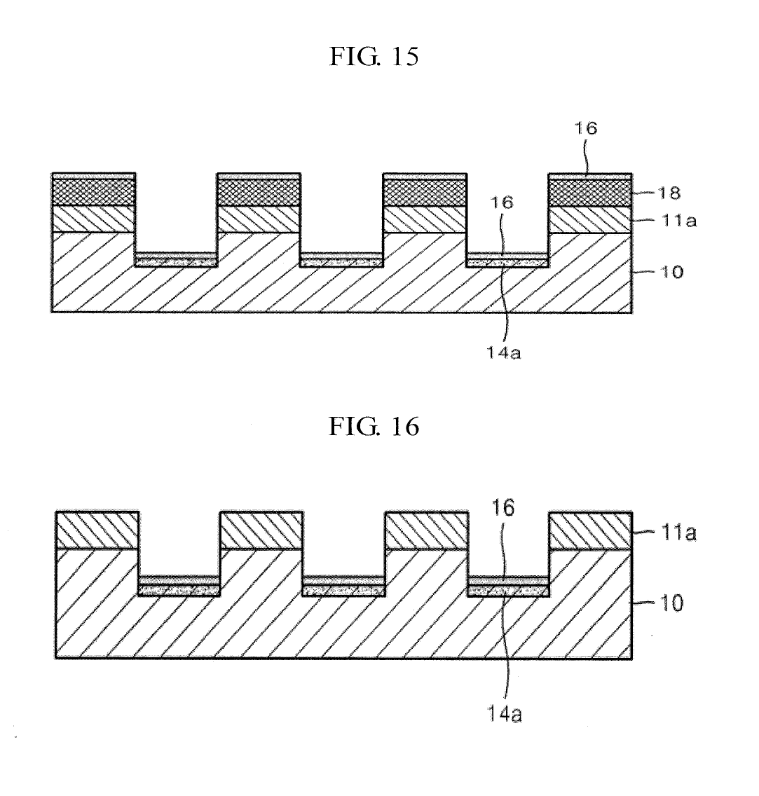

After the passivation film 18 is formed, as illustrated in FIG. 14, the plasma treatment is performed thereon to form the plasma treatment region 14a inside the trench 14. Then, as illustrated in FIG. 15, the seed layer 16 is formed. In this case, the seed layer 16, as illustrated in FIG. 15, may also be formed on the passivation film 18 as well as in the inside of the trench 14. However, as illustrated in FIG. 16, in a subsequent process, the passivation film 18 and the seed layer 16 formed thereon are all removed by selectively removing the passivation film 18.

Then, the hard mask pattern 11a is selectively removed, resulting in the structure as illustrated in FIG. 8, and the residual operations of the method according to the first embodiment are performed.

The present invention will be described in further detail with reference to the following examples. These examples are for illustrative purposes only and are not intended to limit the scope of the present invention.

### Experimental Example

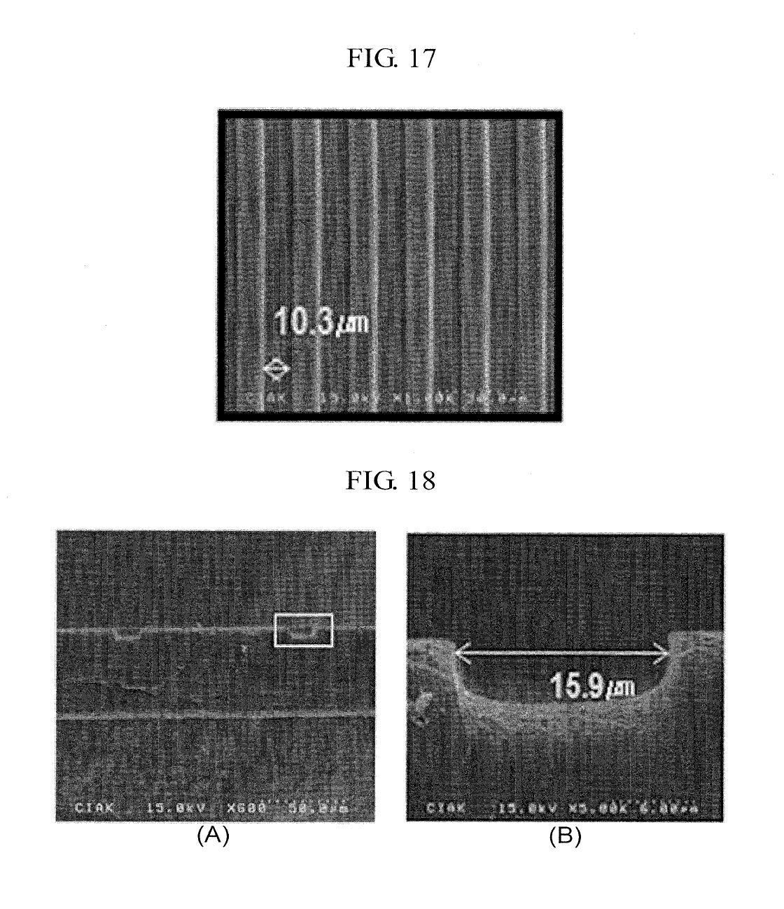

A flexible substrate was formed using polyimide and then a Cr layer as a hard mask was formed thereon. A photoresist film was coated on the Cr layer, and exposure and development processes were performed thereon using ultraviolet (UV) light to form a photoresist film pattern. The photoresist film pattern was designed such that ratios of a trench width W and a distance L between trenches(W:L) are 10 μm:10 μm, 10 μm:20 μm, 10 μm:50 μm, and 10 μm:100 μm. FIG. 17 is an electron microscopic plane image of a sample (W:L=10 μm:10 μm) including a photo-sensitive film patterned on a Cr hard mask according to an embodiment of the present invention.

Then, the Cr hard mask was etched using the photoresist film pattern to form a hard mask pattern, and then by using the hard mask pattern, a portion of the polyimide substrate was etched. The etching was performed for 10 minutes at a process pressure of 300 Torr while feed amounts of oxygen(O₂) and helium(He) were maintained at 200 sccm and 20,000 sccm, respectively, and 200 W of plasma power was applied. In this case, the temperature of the flexible substrate was maintained at 100□.

FIG. 18A shows an electron microscopic image of a cross-section of the polyimide substrate after etching, wherein W:L was 10 μm:50 μm, and FIG. 18B is an enlarged image of the square portion of FIG. 18A. Referring to FIGS. 18A and 18B, it was confirmed that a portion of the polyimide substrate was etched.

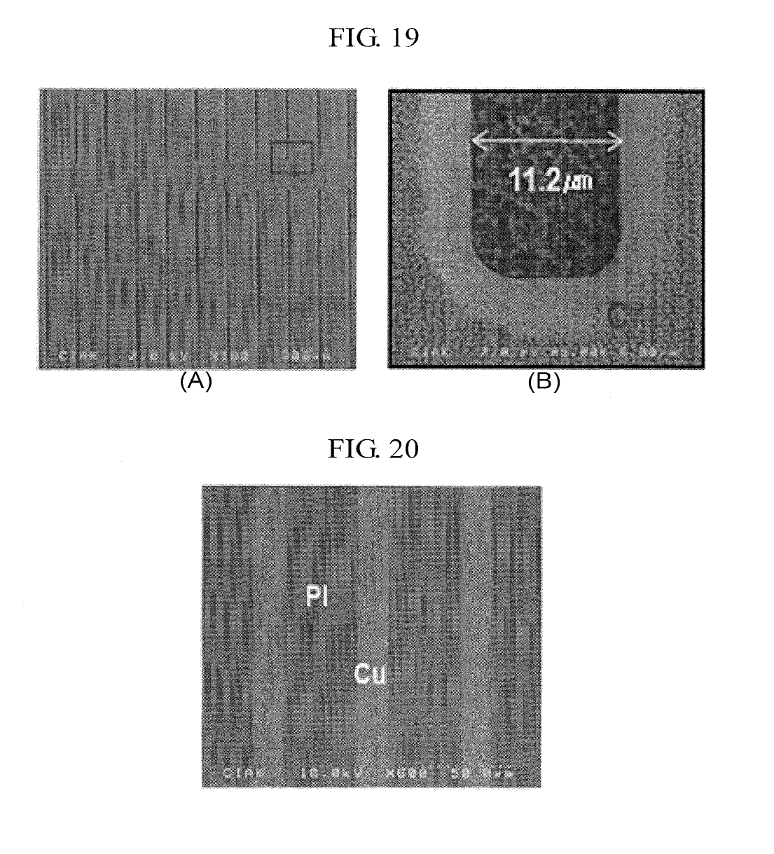

FIG. 19A shows a surface image of a polyimide substrate after etching, and

FIG. 19B shows an enlarged image of the square portion of FIG. 19A. Pl and Cr in FIG. 19B mean polyimide and Cr hard mask, respectively.

Referring to FIGS. 19A and 19B, it was confirmed that during etching, the photoresist film disposed on the Cr hard mask is mostly removed and instead, the Cr hard mask, which had not been removed by the etching, functions as a mask. However, in some cases, a residual photoresist film may be present, and in this case, the photoresist film may be completely removed by using, for example, a DF-300 solution.

Then, a plasma treatment was performed thereon using a mixed gas including helium (He), nitrogen (N₂), and ammonia (NH₃). Detailed process conditions are shown in Table 1 below.

TABLE 1

| Gas and | Plasma | Process | |
|---|---|---|---|
| Feed amount | power | pressure | Treatment time |
| He 2000 sccm | 5 kV | 700 Torr | 1 min and 20 sec |
| N₂ 2000 sccm | | | |
| NH₃ 200 sccm | | | |

After the plasma treatment was completely performed, as a seed layer, a palladium/nickel composite layer was formed. In detail, palladium was coated on the polyimide substrate by electroless plating for 3 minutes and then washed with a sulfuric acid (H₂SO₄) for 3 minutes. Then, a nickel layer was formed on the formed palladium layer by electroless plating for 1 minute.

Then, to remove the Cr hard mask pattern, the resultant structure was immersed in a CR-7 solution for 1 hour and 20 minutes. Once the hard mask pattern was removed, the trench was filled with copper by electroless plating for 5 minutes.

After the trench was formed on the sample (W:L=10 μm:20 μm), a depth of the trench was measured by α-step after one minute of nickel electroless plating and then one minute of copper electroless plating. As a result, when the trench was formed, the trench depth was 0.3 μm, when the nickel electroless plating was performed, the trench depth was reduced to 0.18 μm, and when the copper electroless plating was performed, the trench depth was reduced to 0.16 μm. From these results, it was confirmed that the trench depth was reduced by filling the trench with the nickel layer and the copper layer.

FIG. 20 is an electron microscopic image of the surface of a sample (W:L=10 μm) in which the trench of the polyimide (Pl) substrate is filled with copper (Cu). From the image, it was confirmed that the trench was stably filled with copper.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of forming a metal interconnection line on a flexible substrate, the method comprising:
coating a hard mask layer on at least one surface of the flexible substrate, followed by performing photolithography thereon to form a hard mask pattern;
etching a portion of the flexible substrate by using the hard mask pattern as a mask to form a trench;
plasma treating the inside of the trench by using a treatment gas for pre-treating the flexible substrate;
coating a seed layer inside the trench;
removing the hard mask pattern; and
filling the inside of the trench coated with the seed layer, with metal.

2. The method of claim 1, wherein the removing of the hard mask pattern is performed before the coating the inside of the trench with the seed layer.

3. The method of claim 1, wherein the removing of the hard mask pattern is performed after the coating the inside of the trench with the seed layer.

4. The method of claim 1, further comprising:
forming a passivation film on the hard mask pattern by ink-coating using a roller, after the portion of the flexible substrate is etched by using the hard mask pattern as a mask to form the trench; and
removing the passivation film after the seed layer is formed inside the trench.

5. The method of claim 1, wherein the hard mask layer comprises chrominum (Cr) or aluminum (Al).

6. The method of claim 1, wherein the hard mask layer has a double layer structure formed by sequentially depositing Cr and Al in this stated order.

7. The method of claim 1, wherein a width of the trench is greater than 0 and equal to or greater than 20 μm.

8. The method of claim 1, wherein the plasma-treating of the inside of the trench is performed using atmospheric pressure plasma.

9. The method of claim 1, wherein the treatment gas is an ammonia gas or a mixed gas comprising an ammonia gas, a nitrogen gas, a helium gas, and a hydrogen gas.

10. The method of claim 1, wherein the seed layer comprises a palladium layer.

11. The method of claim 1, wherein the seed layer comprises a palladium/nickel composite layer prepared by coating a palladium layer and coating a nickel layer on the palladium layer.

12. The method of claim 11, further comprising washing the palladium layer with a sulfuric acid after the palladium layer is formed.

13. The method of claim 11 or 11, wherein the palladium layer or the palladium/nickel composite layer is formed by plating.

14. The method of claim 1, wherein the filling the inside of the trench with metal is filing the inside of the trench with copper by plating.
